(19) United States
(12) Patent Application Publication
(10) Pub. No.: US 2024/0222240 A1
(43) Pub. Date: Jul. 4, 2024

(54) POWER SEMICONDUCTOR MODULE AND METHOD OF MANUFACTURING THE SAME

(71) Applicant: HYUNDAI MOBIS CO., LTD., Seoul (KR)

(72) Inventors: Jeong Kwang SEO, Seongnam-si (KR); Yoon Ju KIM, Hwaseong-si (KR); Chan Yang CHOE, Seoul (KR); Yu Cheol PARK, Anyang-si (KR)

(73) Assignee: HYUNDAI MOBIS CO., LTD., Seoul (KR)

(21) Appl. No.: 18/402,916

(22) Filed: Jan. 3, 2024

(30) Foreign Application Priority Data
Jan. 4, 2023 (KR) 10-2023-0001229
Mar. 14, 2023 (KR) 10-2023-0033152

(51) Int. Cl. H01L 23/498; H01L 21/48; H01L 21/56; H01L 23/31; H01L 23/367

(52) U.S. Cl. CPC H01L 23/49811; H01L 21/4853; H01L 21/565; H01L 23/3121; H01L 23/367

(57) ABSTRACT

A power semiconductor module and a method of manufacturing the same are provided. The power semiconductor module is configured so that a power terminal is installed in a direction perpendicular to a surface of a substrate.

### CROSS-REFERENCE TO RELATED APPLICATIONS

This application claims priority under 35 U.S.C. § 119 to Korean Patent Application No. 10-2023-0001229 filed on Jan. 4, 2023, and Korean Patent Application No. 10-2023-0033152 filed on Mar. 14, 2023, in the Korean Intellectual Property Office, the disclosures of which are incorporated herein by reference in their entireties.

### BACKGROUND

### 1. Field

The following disclosure relates to a power semiconductor and method of manufacturing the same, and more particularly, to a power semiconductor module with reduced inductance and a small volume and a method of manufacturing the same.

### 2. Description of Related Art

A power semiconductor is a semiconductor that is composed of a power switching device and a control integrated circuit (IC) and serves to convert, divide, and manage power applied to electronic devices.

The power semiconductor requires high pressure durability, high reliability, etc., compared to general semiconductors, and demand for the power semiconductor is increasing due to the development of hybrid vehicles and electric vehicles.

A power semiconductor module used in the hybrid vehicles and the electric vehicles is composed of power semiconductor devices used to convert direct current (DC) into alternate current (AC) or AC into DC. The power semiconductor module is implemented through major technologies such as module integration design technology, manufacturing process technology, and characteristic testing and reliability evaluation technology of the power semiconductor devices and packaging materials, and needs to have high durability and reliability since the power semiconductor module should operate in harsh environments such as high temperature environments or strong vibration environments.

Meanwhile, in a conventional power semiconductor module, a power terminal is installed on a substrate in a lateral direction parallel to the substrate.

FIG. 1 is a diagram illustrating the conventional power semiconductor module.

Specifically, describing with reference to FIG. 1, a conventional power semiconductor module 100 includes a substrate 110, a semiconductor 120, a power terminal 130, and a molding part 140, and the power terminal 130 is installed on the substrate in a lateral direction parallel to the substrate 110 in order to secure an insulating distance 11 from the substrate 110. The substrate 110 may include an insulating layer 111 sandwiched between a first metal layer 112 and a second metal layer 113.

In this way, when the power terminal 130 is installed on the substrate 110 to secure the insulating distance 11, a volume of the molding part 140 increases, and a partial length 12 of the power terminal 130 becomes longer and thus an overall length of the power terminal 130 also becomes longer.

In this way, there is problem in that when the volume of the molding part 140 increases, there is a problem in that the overall volume of the power semiconductor module increases, and when the overall length of the power terminal 130 increases, the inductance increases.

Therefore, there is a need to develop a power semiconductor module that has a small volume and may have reduced inductance.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect of the disclosure, a power semiconductor module, includes: a substrate having an insulating layer including an upper surface and a lower surface, a first metal layer including a lower surface coupled to the upper surface of the insulating layer, and a second metal layer including an upper surface coupled to the lower surface of the insulating layer; a semiconductor coupled to an upper surface of the first metal layer, the semiconductor electrically connected to at least a portion of the first metal layer; a power terminal including one end coupled to an upper surface of the first metal layer and electrically connected to at least a portion of the first metal layer so that an imaginary line segment connecting one end and the other end is perpendicular to the upper surface of the first metal layer; and a molding part coupled to the substrate to surround the second metal layer excluding a lower surface of the second metal layer, the power terminal excluding the other end of the power terminal, the insulating layer, the first metal layer, and the semiconductor.

The power terminal may be formed to extend in a longitudinal direction.

The power terminal may include at least one of copper, a copper alloy, aluminum, an aluminum alloy, a light metal material, a heat-treated material, a porous material, or any combination thereof.

The insulating layer may include ceramic, and the first metal layer and the second metal layer may each include at least one of copper, aluminum, or a combination thereof.

In another general aspect of the disclosure, a method of manufacturing a power semiconductor module includes: a preparation step of preparing a substrate including an insulating layer including an upper surface and a lower surface, a first metal layer including a lower surface coupled to the upper surface of the insulating layer, and a second metal layer including an upper surface coupled to the lower surface of the insulating layer; a first installation step of coupling a semiconductor to an upper surface of the first metal layer to be electrically connected to at least a portion of the first metal layer; a second installation step of coupling a power terminal, the power terminal including a first end coupled to the upper surface of the first metal layer and is electrically connected to at least a portion of the first metal layer so that an imaginary line segment connecting one end, and a second end directed toward an upper portion of the upper surface of the first metal layer; a molding step of arranging the substrate in an internal space surrounded by a lower molding mold and an upper molding mold and injecting a molding material into the internal space to form a molding part coupled to the substrate; and a separation step of separating the substrate from the lower molding mold and the upper molding mold, wherein, when the substrate is arranged in the internal space and the upper molding mold presses the second end of the power terminal, the second end of the power terminal is bent in a direction toward the first end.

The power terminal may include an elastomer.

The substrate may be arranged in the internal space and the upper molding mold presses the second end of the power terminal, a shape of the power terminal is deformed so that a distance between the first end and the second end is shortened.

The method may further include, after the separation step, a removal step of removing at least a portion of the protective member coupled to the substrate so that the second end of the power terminal is externally exposed.

When the substrate is arranged in the internal space, the distance between the first end and the second end of the power terminal may be longer than the distance between the first end of the power terminal and the protective member, and shorter than the distance between the first end of the power terminal and a surface of the upper molding mold.

After the separation step, a processing step of removing at least a portion of the molding part coupled to the substrate so that the second end of the power terminal may be exposed externally, wherein, when the substrate is arranged in the internal space, the distance between the first end and the second end of the power terminal may be shorter than the distance between the first end of the power terminal and a surface of the upper molding mold opposite to the lower molding mold.

In yet another aspect of the disclosure, a power semiconductor module may include: a substrate on which a conductive pattern is formed; a power terminal coupled to the substrate and electrically connected to at least some of the patterns; a semiconductor installed on the substrate and electrically connected to at least some of the patterns and the power terminal; a molding part covering the semiconductor and the substrate; and a heat dissipation member provided under the substrate to cool the substrate, wherein the molding part includes: a body part covering the semiconductor, the substrate, and a portion of the power terminal; and a cover part provided to extend to an outside of the body part by a predetermined length so that a lower area of the molding part is larger than an upper area of the heat dissipation member.

The power terminal may include: a coupling part coupled to the substrate; a bent part bent at a predetermined angle from the coupling part; and an extension extending from the bent part to the outside of the molding part in a direction parallel to the substrate, and the cover part may be provided in a direction parallel to the extension.

The power semiconductor module of claim 11, wherein the cover part is provided at a lower end of the body.

The heat dissipation member may include: a contact part in contact with the substrate; and a step part having a larger area than the contact part and forming a step with respect to the contact part under the contact part, and the cover part may be provided on the step part.

The cover part may extend downward along an edge of the heat dissipation member to cover an upper portion of the heat dissipation member.

A protrusion may be formed toward the outside of the cover part.

The power terminal may include: a coupling part coupled to the substrate; a bent part bent at a predetermined angle from the coupling part; and an extension extending from the bent part to an outside of the molding part in a direction parallel to the substrate, and wherein the cover part may be provided in a direction perpendicular to the extending part.

The cover part may include: an inclined part provided to have a predetermined downward inclination from the body part; and an extending cover part bent from the inclined part and extending downward along an edge of the heat dissipation member to cover an upper part of the heat dissipation member, and the cover part may be provided in a direction perpendicular to the extending part.

The heat dissipation member may include: a contact part in contact with the substrate; and a step part having a larger area than the contact part and forming a step with respect to the contact part under the contact part, and the inclined part may be provided on the step part and the extending cover part is provided to cover an upper edge of the step part.

The inclined part may be provided so that an inner side adjacent to the step part is spaced apart from the contact part with a predetermined gap.

The power semiconductor module may be sized and configured to have a volume smaller than a conventional power semiconductor module.

The power semiconductor module may be configured to have a smaller inductance than a conventional power semiconductor module.

The insulating layer may be formed of ceramic, and the first metal layer and the second metal layer may each comprise copper, aluminum or a combination thereof.

### BRIEF DESCRIPTION OF THE DRAWINGS

FIG. 1 is a diagram illustrating a conventional power semiconductor module.

FIG. 2 is a diagram illustrating a power semiconductor module according to an embodiment of the present invention.

FIG. 3 is a flowchart illustrating a method of manufacturing a power semiconductor module according to a first embodiment of the present invention.

FIG. 4 is a diagram illustrating an appearance in which one end of a power terminal is bent in a direction toward the other end when a substrate is arranged in an internal space surrounded by a lower molding mold and an upper molding mold according to the manufacturing method of FIG. 3.

FIG. 5 is a flowchart illustrating a method of manufacturing a power semiconductor module according to a second embodiment of the present invention.

FIG. 6 is a diagram illustrating an appearance in which a shape of a power terminal is deformed so that a distance between one end of a power terminal and the other end is shortened when a substrate is arranged in an internal space surrounded by a lower molding mold and an upper molding mold according to the manufacturing method of FIG. 5.

FIG. 7 is a flowchart illustrating a method of manufacturing a power semiconductor module according to a third embodiment of the present invention.

FIG. 8 is a diagram illustrating an appearance in which a substrate is arranged in an internal space surrounded by a lower molding mold and an upper molding mold provided with a protective member according to the manufacturing method of FIG. 7.

FIG. 9 is a flowchart illustrating a method of manufacturing a power semiconductor module according to a fourth embodiment of the present invention.

FIG. 10 is a diagram illustrating an appearance in which a substrate is arranged in an internal space surrounded by a lower molding mold and an upper molding mold according to the manufacturing method of FIG. 9.

FIG. 11 is a diagram illustrating the power semiconductor module from which at least a portion of a protective member coupled to the substrate is removed.

FIG. 12 is a diagram illustrating a power semiconductor module according to another embodiment of the present invention.

FIGS. 13, 14A, 14B, 14C, 15, 16A, 16B, and 16C are diagrams illustrating a power semiconductor module according to other embodiments of the present invention.

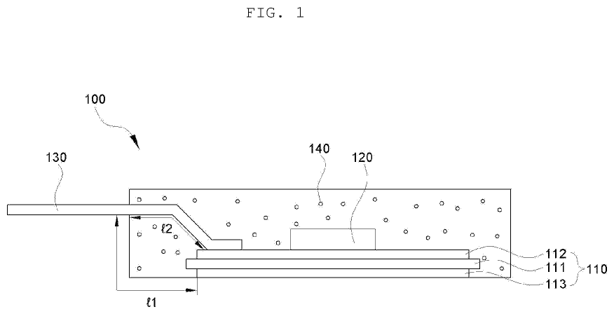

### DETAILED DESCRIPTION

Hereinafter, exemplary embodiments of the present disclosure will be described in detail with reference to the accompanying drawings so that those skilled in the art to which the present disclosure pertains may easily practice. However, the present disclosure may be implemented in various different forms, and is not limited to the embodiments described herein. In addition, in the drawings, portions unrelated to the description will be omitted to clearly describe the present disclosure, and similar portions will be denoted by similar reference numerals throughout the specification.

Throughout the present specification, when any one part is referred to as being “connected to” another part, it means that any one part and another part are “directly connected to” each other or are “electrically connected to” each other with still another part interposed therebetween.

Throughout the present specification, when any member is referred to as being positioned “on” other member, it includes not only a case in which any member and another member are in contact with each other, but also a case in which the other member is interposed between any member and another member.

Throughout the present specification, “including” any component will be understood to imply the inclusion of other components rather than the exclusion of other components, unless explicitly described to the contrary. The terms “about,” “substantially,” and the like used throughout the present specification means figures corresponding to manufacturing and material tolerances specific to the stated meaning and figures close thereto, and are used to prevent unconscionable abusers from unfairly using the disclosure of figures precisely or absolutely described to aid the understanding of the present disclosure. The term “˜step” or “˜step of” used throughout the present specification of the present invention does not mean “˜step for.”

Hereinafter, embodiments of the present invention will be described in detail with reference to the accompanying drawings. However, the present invention is not limited to exemplary embodiments herein, but may be implemented in other forms. Same reference numerals denote same constituent elements throughout the specification.

Hereinafter, a power semiconductor module according to an embodiment of the present invention will be described.

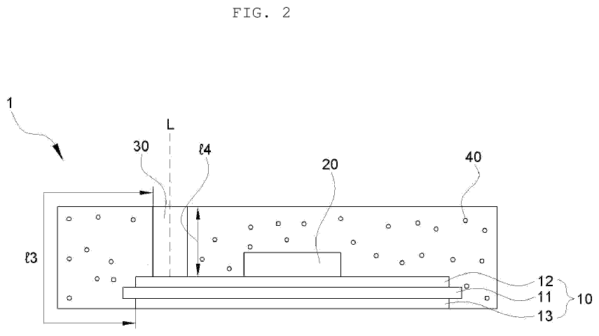

FIG. 2 is a diagram illustrating a power semiconductor module according to an embodiment of the present invention.

Describing with reference to FIG. 2, a power semiconductor module 1 includes a substrate 10, a semiconductor 20, a power terminal 30, and a molding part 40.

First, the substrate 10 will be described.

The substrate 10 includes an insulating layer 11, a first metal layer 12, and a second metal layer 13.

The insulating layer 11 may be formed of ceramic, etc.

The first metal layer 12 may have one surface coupled to one surface of the insulating layer 11, may be formed of copper, aluminum or the like, and may be formed with a pattern capable of conducting electricity to the other surface (hereinafter referred to as a pattern).

The second metal layer 13 may have one surface coupled to the other surface of the insulating layer 11 and may be formed of copper, aluminum, etc.

Next, the semiconductor 20 will be described.

The semiconductor 20 may be formed in a structure in which a plurality of power devices are bonded in parallel to a metal wiring formed on a predetermined substrate, and coupled to the other surface of the first metal layer 12 to be electrically connected to at least a portion of the first metal layer 12 of the substrate 10.

The semiconductor 20 may receive power from the power terminal 30 and may be formed of the conventional semiconductor, etc.

Next, the power terminal 30 will be described.

The power terminal 30 may be coupled to the other surface of the first metal layer 12 of the substrate 10 through soldering using solder through welding using ultrasonic waves and lasers, and may be electrically connected to at least some of the patterns formed on the first metal layer 12.

One end of the power terminal 30 may be coupled to the other surface of the first metal layer 12 so that an imaginary line segment L connecting one end and the other end is perpendicular to the other surface of the first metal layer 12.

For example, the power terminal 30 may be formed to extend in a longitudinal direction and coupled to the first metal layer 12 so as to be perpendicular to the other surface of the first metal layer 12, and may be formed of copper, a copper alloy, aluminum, an aluminum alloy, and a light metal material, or may be formed of a heat-treated material or a porous material.

Next, the molding part 40 will be described.

The molding part 40 may be formed to embed components including the semiconductor 20 installed on the substrate 10.

Specifically, the molding part 40 may be coupled to the second metal layer 13 excluding the other surface of the second metal layer 13, the power terminal 30 excluding the other end of the power terminal 30, the insulating layer 11, and the substrate 10 to surround the first metal layer 12 and the semiconductor 20.

In addition, the molding part 40 may be made of a polymer material with excellent insulating and protective properties. For example, the molding part 40 may be made of a material including epoxy molding compound (EMC).

When the molding part 40 is formed in this way, components such as the semiconductor 20 embedded within the molding part 40 may be protected by the molding part 40.

Meanwhile, in the power semiconductor module 1, one end of the power terminal 30 may be coupled to the other surface of the first metal layer 12 so that the imaginary line segment L connecting one end and the other end is perpendicular to the other surface of the first metal layer 12, so the overall length 14 of the power terminal 30 becomes shorter than the overall length of the power terminal installed in the conventional power semiconductor module.

In addition, in the power semiconductor module 1, one end of the power terminal 30 may be coupled to the other surface of the first metal layer 12 so that the imaginary line segment L connecting one end and the other end is perpendicular to the other surface of the first metal layer 12, so even if the molding part 40, which has a smaller volume than the molding part installed in the conventional power semiconductor module, is installed on the substrate 10, similar to the insulating distance 11 of the conventional power semiconductor, it is possible to secure a sufficient insulating distance 13.

That is, since the length of the power terminal 30 may be shorter, the inductance of the power semiconductor module 1 may be reduced, and since the volume of the molding part 40 may be reduced, the volume of the power semiconductor module 1 may be reduced.

Hereinafter, a method of manufacturing a power semiconductor module according to a first embodiment of the present invention will be described.

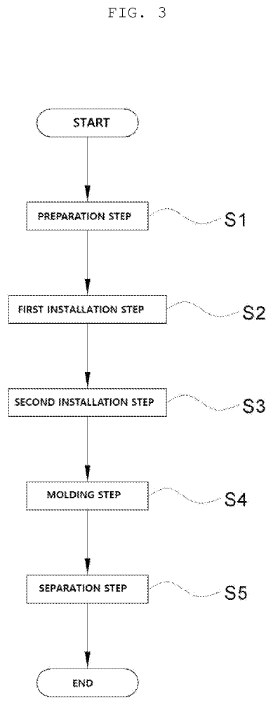

FIG. 3 is a flowchart illustrating a method of manufacturing a power semiconductor module according to the first embodiment of the present invention.

Referring to FIG. 3, the method of manufacturing a power semiconductor module includes a preparation step (S1), a first installation step (S2), a second installation step (S3), a molding step (S4), and a separation step (S5).

First, the preparation step (S1) will be described.

The preparation step (S1) is a step of preparing the substrate 10 that includes an insulating layer 11, a first metal layer 12 whose one surface is coupled to one surface of the insulating layer 11, and a second metal layer 13 whose one surface is coupled to the other surface of the insulating layer 11.

The insulating layer 11 may be formed of ceramic, etc.

The first metal layer 12 may have one surface coupled to one surface of the insulating layer 11, may be formed of copper, aluminum or the like, and may be formed with a pattern capable of conducting electricity to another surface (hereinafter referred to as a pattern).

The second metal layer 13 may have one surface coupled to another surface of the insulating layer 11 and may be formed of copper, aluminum, etc.

Next, the first installation step (S2) will be described.

The first installation step (S2) is a step of coupling the semiconductor 20 to the other surface of the first metal layer 12 so as to be electrically connected to at least a portion of the first metal layer 12.

The semiconductor 20 may be formed in a structure in which a plurality of power devices are bonded in parallel to a metal wiring formed on a predetermined substrate.

Next, the second installation step (S3) will be described.

The second installation step (S3) is a step of coupling the power terminal 30 to the first metal layer 12.

Specifically, the second installation step (S3) is a step of coupling the power terminal 30, which has one end coupled to the other surface of the first metal layer 12 and is electrically connected to at least a portion of the first metal layer 12, to the first metal layer 12 so that the imaginary line segment L connecting one end and the other end is directed toward an upper portion of the other surface of the first metal layer 12.

In this case, the power terminal 30 may be formed of an elastomer.

Next, the molding step (S4) will be described.

The molding step (S4) is a step of disposing the substrate 10 in an internal space surrounded by the lower molding mold 2 and the upper molding mold 3, and injecting the molding material into the internal space to form the molding part 40 coupled to the substrate 10.

Meanwhile, as described above, when the substrate 10 is arranged in the internal space, in order to prevent damage to the substrate 10 etc., due to interference occurring between the power terminal 30 coupled in a direction perpendicular to the substrate 10 and the upper molding mold 3, the power terminal 30 may be formed of the elastomer.

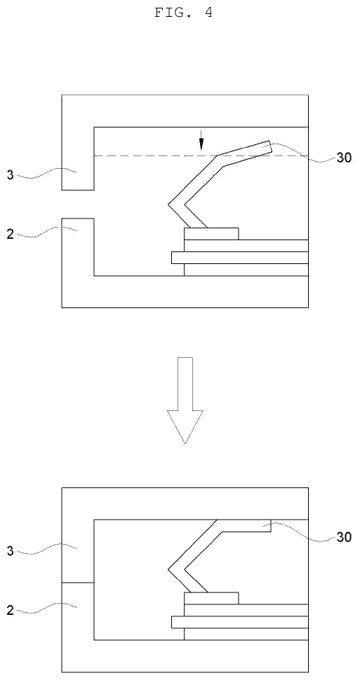

FIG. 4 is a diagram illustrating an appearance in which one end of a power terminal is bent in a direction toward the other end when a substrate is arranged in an internal space surrounded by a lower molding mold and an upper molding mold according to the manufacturing method of FIG. 3.

Specifically, as illustrated in FIG. 4, the power terminal 30 is formed of an elastomer whose shape may be deformed when being applied with force, so that when the upper molding mold 3 presses the other end of the power terminal 30, the power terminal 30 may be bent in a direction in which the other end is directed toward the one end.

Therefore, the substrate 10 may be arranged in the internal space while preventing the power terminal 30 from damaging the substrate 10, etc.

After the substrate 10 is arranged in the internal space, the molding material injected into the internal space to form the molding part 40 may be formed of a polymer material with excellent insulating and protective properties. For example, the molding material may be formed of a material including epoxy molding compound (EMC).

Next, the separation step (S5) will be described.

The separation step (S5) is a step of separating the substrate 10 from the lower molding mold 2 and the upper molding mold 3.

Through the separation step (S5), the substrate 10 to which the power terminal 30 whose other end is exposed to the outside of the molding part 40 is coupled may be manufactured.

Hereinafter, a method of manufacturing a power semiconductor module according to a second embodiment of the present invention will be described.

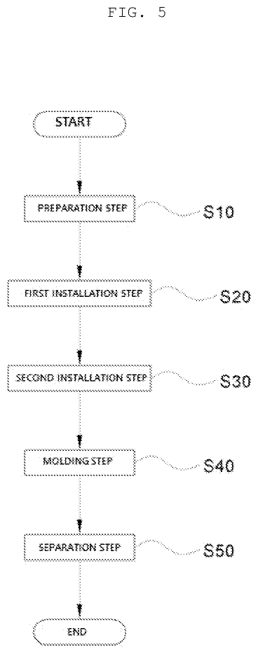

FIG. 5 is a flowchart illustrating a method of manufacturing a power semiconductor module according to the second embodiment of the present invention.

Referring to FIG. 5, the method of manufacturing a power semiconductor module includes a preparation step (S10), a first installation step (S20), a second installation step (S30), a molding step (S40), and a separation step (S50).

First, the preparation step (S10) will be described.

The preparation step (S10) is a step of preparing the substrate 10 that includes an insulating layer 11, a first metal layer 12 whose one surface is coupled to one surface of the insulating layer 11, and a second metal layer 13 whose one surface is coupled to the other surface of the insulating layer 11.

The insulating layer 11 may be formed of ceramic, etc.

The first metal layer 12 may be coupled to one surface of the insulating layer 11, may be formed of copper, aluminum or the like, and may be formed with a pattern capable of conducting electricity to another surface (hereinafter referred to as a pattern).

The second metal layer 13 may have one surface coupled to another surface of the insulating layer 11 and may be formed of copper, aluminum, etc.

Next, the first installation step (S20) will be described.

The first installation step (S20) is a step of coupling the semiconductor 20 to the other surface of the first metal layer 12 so as to be electrically connected to at least a portion of the first metal layer 12.

The semiconductor 20 may be formed in a structure in which a plurality of power devices are bonded in parallel to a metal wiring formed on a predetermined substrate.

Next, the second installation step (S30) will be described.

The second installation step (S30) is a step of coupling the power terminal 30 to the first metal layer 12.

Specifically, the second installation step (S30) is a step of coupling one end to the other surface of the first metal layer 12 to couple the power terminal 30 electrically connected to at least a portion of the first metal layer 12 to the first metal layer 12 so that the imaginary line segment L connecting one end and the other end is perpendicular to the other surface of the first metal layer 12.

In this case, the power terminal 30 may be formed of a material whose shape is deformed so that when one end is pressed in a direction toward the other end, the distance between one end and the other end is shortened.

For example, the power terminal 30 may be formed of a material with a Brinell hardness of 73 or less, or may be formed of a heat-treated material.

Next, the molding step (S40) will be described.

The molding step (S40) is a step of disposing the substrate 10 in an internal space surrounded by the lower molding mold 2 and the upper molding mold 3, and injecting the molding material into the internal space to form the molding part 40 coupled to the substrate 10.

Meanwhile, as described above, when the substrate 10 is arranged in the internal space, in order to prevent damage to the substrate 10 etc., due to interference occurring between the power terminal 30 coupled in a direction perpendicular to the substrate 10 and the upper molding mold 3, the power terminal 30 may be made of copper, a copper alloy, aluminum, an aluminum alloy, a light metal material, a heat-treated material, or a porous material.

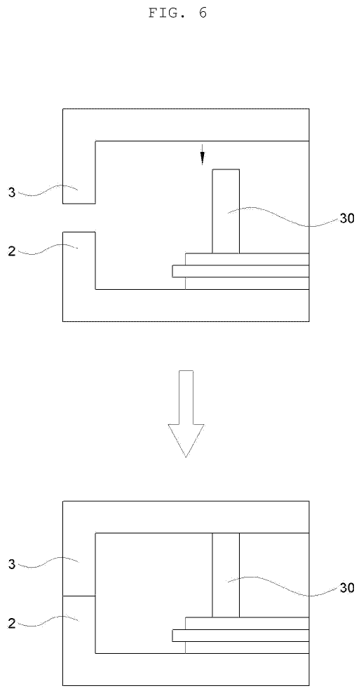

FIG. 6 is a diagram illustrating an appearance in which a shape of a power terminal is deformed so that a distance between one end of a power terminal and the other end is shortened when a substrate is arranged in an internal space surrounded by a lower molding mold and an upper molding mold according to the manufacturing method of FIG. 5.

Specifically, as illustrated in FIG. 6, the power terminal 30 may be formed of copper, a copper alloy, aluminum, an aluminum alloy, a light metal material, a heat-treated material, or a porous material, so when the upper molding mold 3 presses the other end of the power terminal 30, the shape of the power terminal 30 may be deformed so that the distance between one end and the other end is shortened.

Therefore, the substrate 10 may be arranged in the internal space while preventing the power terminal 30 from damaging the substrate 10, etc.

After the substrate 10 is arranged in the internal space, the molding material injected into the internal space to form the molding part 40 may be formed of a polymer material with excellent insulating and protective properties. For example, the molding material may be formed of a material including epoxy molding compound (EMC).

Next, the separation step (S50) will be described.

The separation step (S50) is a step of separating the substrate 10 from the lower molding mold 2 and the upper molding mold 3.

Through the separation step (S50), the substrate 10 to which the power terminal 30 whose other end is exposed to the outside of the molding part 40 is coupled may be manufactured.

Hereinafter, a method of manufacturing a power semiconductor module according to a third embodiment of the present invention will be described.

FIG. 7 is a flowchart illustrating the method of manufacturing a power semiconductor module according to the third embodiment of the present invention.

Referring to FIG. 7, the method of manufacturing a power semiconductor module includes a preparation step (S100), a first installation step (S200), a second installation step (S300), a third installation step (S400), a molding step (S500), a separation step (S600), and a removal step (S700).

First, the preparation step (S100) will be described.

The preparation step (S100) is a step of preparing the substrate 10 that includes an insulating layer 11, a first metal layer 12 whose one surface is coupled to one surface of the insulating layer 11, and a second metal layer 13 whose one surface is coupled to the other surface of the insulating layer 11.

The insulating layer 11 may be formed of ceramic, etc.

The first metal layer 12 may have one surface coupled to one surface of the insulating layer 11, may be formed of copper, aluminum or the like, and may be formed with a pattern capable of conducting electricity to another surface (hereinafter referred to as a pattern).

The second metal layer 13 may have one surface coupled to another surface of the insulating layer 11 and may be formed of copper, aluminum, etc.

Next, the first installation step (S200) will be described.

The first installation step (S200) is a step of coupling the semiconductor 20 to the other surface of the first metal layer 12 so as to be electrically connected to at least a portion of the first metal layer 12.

The semiconductor 20 may be formed in a structure in which a plurality of power devices are bonded in parallel to a metal wiring formed on a predetermined substrate.

Next, the second installation step (S300) will be described.

The second installation step (S300) is a step of coupling the power terminal 30 to the first metal layer 12.

Specifically, the second installation step (S300) is a step of coupling one end to the other surface of the first metal layer 12 to couple the power terminal 30 electrically connected to at least a portion of the first metal layer 12 to the first metal layer 12 so that the imaginary line segment L connecting one end and the other end is perpendicular to the other surface of the first metal layer 12.

Next, the third installation step (S400) will be described.

The third installation step (S400) is a step of installing a protective member 3-1 having a predetermined thickness on one surface of the upper molding mold 3 opposite to the lower molding mold 2.

The protective member 3-1 may be formed of a material with less strength than the power terminal 30.

Next, the molding step (S500) will be described.

The molding step (S500) is a step of disposing the substrate 10 in an internal space surrounded by the lower molding mold 2 and the upper molding mold 3, and injecting the molding material into the internal space to form the molding part 40 coupled to the substrate 10.

Meanwhile, since the protective member 3-1 is installed on one surface of the upper molding mold 3, interference occurs between the power terminal 30 coupled in a direction perpendicular to the substrate 10 and the upper molding mold 3 when the substrate 10 is arranged in the internal space, thereby preventing damage to the substrate 10 etc.

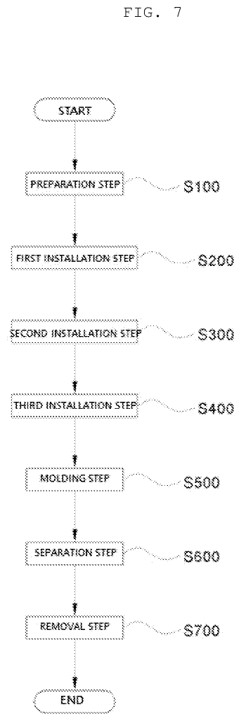

FIG. 8 is a diagram illustrating an appearance in which a substrate is arranged in an internal space surrounded by a lower molding mold and an upper molding mold provided with a protective member according to the manufacturing method of FIG. 7.

For example, as illustrated in FIG. 8, since the other end of the power terminal 30 is configured to contact the protective member 3-1 when the substrate 10 is arranged in the internal space so that a portion of the power terminal 30 is inserted into the protective member 3-1, the power terminal 30 may be pressed by the upper molding mold 3, thereby preventing damage to the substrate 10, etc.

In this way, in order for a portion of the power terminal 30 to be inserted into the protective member 3-1 when the substrate 10 is arranged in the internal space, it is preferable that the distance between one end and the other end of the power terminal 30 is longer than the distance between one end of the power terminal 30 and the protective member 3-1 and shorter than the distance between one end of the power terminal 30 and one surface of the upper molding mold 3.

After the substrate 10 is arranged in the internal space, the molding material injected into the internal space to form the molding part 40 may be formed of a polymer material with excellent insulating and protective properties. For example, the molding material may be formed of a material including epoxy molding compound (EMC).

Next, the separation step (S600) will be described.

The separation step (S600) is a step of separating the substrate 10 from the lower molding mold 2 and the upper molding mold 3.

Next, the removal step (S700) will be described.

The removal step (S700) is a step of removing at least a portion of the protective member coupled to the substrate 10 so that the other end of the power terminal 30 is exposed to the outside of the molding part 40.

Through the removal step (S700), the substrate 10 to which the power terminal 30 whose other end is exposed to the outside of the molding part 40 is coupled may be manufactured.

Hereinafter, a method of manufacturing a power semiconductor module according to a fourth embodiment of the present invention will be described.

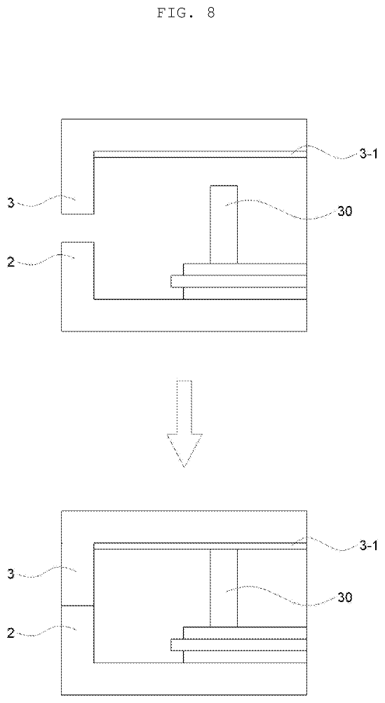

FIG. 9 is a flowchart illustrating the method of manufacturing a power semiconductor module according to the fourth embodiment of the present invention.

Referring to FIG. 9, the method of manufacturing a power semiconductor module includes a preparation step (S1000), a first installation step (S2000), a second installation step (S3000), a molding step (S4000), a separation step (S5000), and a processing step (S6000).

First, the preparation step (S1000) will be described.

The preparation step (S1000) is a step of preparing the substrate 10 that includes an insulating layer 11, a first metal layer 12 whose one surface is coupled to one surface of the insulating layer 11, and a second metal layer 13 whose one surface is coupled to the other surface of the insulating layer 11.

The insulating layer 11 may be formed of ceramic, etc.

The first metal layer 12 may have one surface coupled to one surface of the insulating layer 11, may be formed of copper, aluminum or the like, and may be formed with a pattern capable of conducting electricity to another surface (hereinafter referred to as a pattern).

The second metal layer 13 may have one surface coupled to another surface of the insulating layer 11 and may be formed of copper, aluminum, etc.

Next, the first installation step (S2000) will be described.

The first installation step (S2000) is a step of coupling the semiconductor 20 to the other surface of the first metal layer 12 so as to be electrically connected to at least a portion of the first metal layer 12.

The semiconductor 20 may be formed in a structure in which a plurality of power devices are bonded in parallel to a metal wiring formed on a predetermined substrate.

Next, the second installation step (S3000) will be described.

The second installation step (S3000) is a step of coupling the power terminal 30 to the first metal layer 12.

Specifically, the second installation step (S300) is a step of coupling one end to the other surface of the first metal layer 12 to couple the power terminal 30 electrically connected to at least a portion of the first metal layer 12 to the first metal layer 12 so that the imaginary line segment L connecting one end and the other end is perpendicular to the other surface of the first metal layer 12.

In this case, the power terminal 30 may be formed so that the distance between one end and the other end of the power terminal 30 is shorter than the distance between one end of the power terminal 30 and one surface of the upper molding mold 3 opposite to the lower molding mold 2.

Next, the molding step (S4000) will be described.

The molding step (S4000) is a step of disposing the substrate 10 in an internal space surrounded by the lower molding mold 2 and the upper molding mold 3, and injecting the molding material into the internal space to form the molding part 40 coupled to the substrate 10.

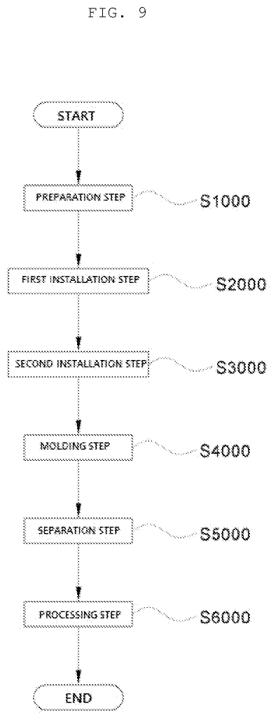

FIG. 10 is a diagram illustrating an appearance in which a substrate is arranged in an internal space surrounded by a lower molding mold and an upper molding mold according to the manufacturing method of FIG. 9.

Describing with reference to FIG. 10, since the power terminal 30 is formed so that the distance between one end and the other end of the power terminal 30 is shorter than the distance between one end of the power terminal 30 and one surface of the upper molding mold 3 opposite to the lower molding mold 2, when the substrate 10 is arranged in the internal space, the other end of the power terminal 30 does not contact one surface of the upper molding mold 3.

Accordingly, it is possible to prevent the power terminal 30 from damaging the substrate 10, etc., when pressed by the upper molding mold 3.

Next, the separation step (S5000) will be described.

The separation step (S5000) is a step of separating the substrate 10 from the lower molding mold 2 and the upper molding mold 3.

Next, the processing step (S6000) will be described.

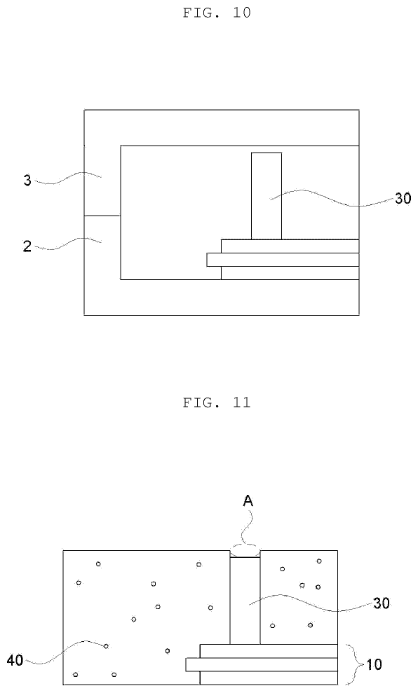

FIG. 11 is a diagram illustrating the power semiconductor module from which at least a portion of a protective member coupled to the substrate is removed.

As illustrated in FIG. 11, the processing step (S6000) is a step of removing at least a portion A of the molding part 40 coupled to the substrate 10 so that the other end of the power terminal 30 is exposed to the outside.

Through the processing step (S6000), the substrate 10 to which the power terminal 30 whose other end is exposed to the outside of the molding part 40 is coupled may be manufactured.

According to the power semiconductor module and method of manufacturing the same according to the present invention, since the power terminal is installed to extend in the direction perpendicular to one surface of the substrate, the volume of the molding part may be reduced to secure the insulating distance, so it is possible to allow the power semiconductor module to have the smaller volume.

In addition, since the length of the power terminal may be shorter, it is possible to reduce the inductance of the power semiconductor module.

In addition, since there is no need to install the power terminal on the substrate so that the power terminal protrudes in the side direction parallel to the substrate, the power terminal may be freely arranged at a position on the power semiconductor module, so it is possible to increase the degree of freedom of installation of the power terminal on the substrate.

Hereinafter, a power semiconductor module 200 according to another embodiment of the present invention will be described.

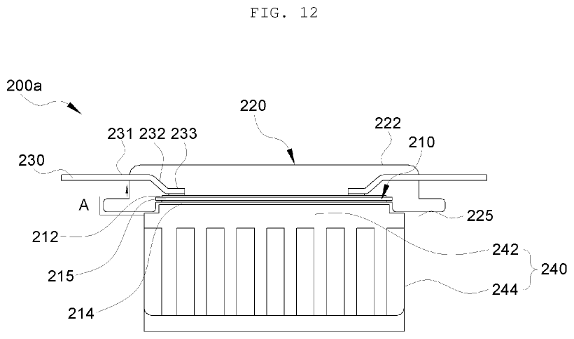

FIG. 12 is a diagram illustrating a power semiconductor module 200 according to another embodiment of the present invention. Referring to FIG. 12, the power semiconductor module 200 may include a substrate 210, a power terminal 230, a molding part 220, and a heat dissipation member 240.

A conductive pattern is formed on the substrate 210. A semiconductor (not illustrated) is installed on the substrate 210 and is electrically connected to at least a portion of the pattern and a power terminal 230 to be described later. In one example, the substrate 210 includes a first metal layer 212 and a second metal layer 214, and an insulating layer 215 may be provided between the first metal layer 212 and the second metal layer 214.

The semiconductor (not illustrated) may be formed in a structure where a plurality of power devices are bonded in parallel to a metal wiring formed on a predetermined substrate 210, and may be installed on the second metal layer 214. In addition, the semiconductor (not illustrated) may include a signal unit capable of transmitting and receiving signals and a power unit electrically connected to the pattern formed on the second metal layer 214.

In one example, the first metal layer 212 and the second metal layer 214 may be provided as a metal layer with good conductivity such as copper. A conductive pattern may be formed on one surface of the first metal layer 212 opposite to the second metal layer 214. However, this is only an example of the substrate 210 and the semiconductor, and the present invention may be applied to the substrate 210 and the semiconductor provided in various forms.

The power terminal 230 may include a coupling part 233 coupled to the substrate 210, a bent part 232 bent at a predetermined angle from the coupling part 233, and an extension 231 extending from the bent part 232 to the outside of the molding part 220 in a parallel direction to the substrate 210. The power terminal 230 serves to connect the substrate 210 and external electrical elements. In one example, one side of the power terminal 230 may be connected to the substrate 210 and the other side may be connected to a capacitor. In one example, the power terminal 230 may be provided as an elastomer. In one example, the power terminal 230 may be made of copper, a copper alloy, aluminum, an aluminum alloy, a light metal, a heat-treated material, or a porous material.

The molding part 220 is provided to cover the semiconductor, the substrate 210, and a portion of the power terminal 230. The molding part 220 may be formed of a polymer material with excellent insulating and protective properties. In one example, the molding part 220 may include epoxy molding compound (EMC). When the molding part 220 is formed in this way, components such as the semiconductor (not illustrated) embedded within the molding part 220 may be protected by the molding part 220.

In one example, the molding part 220 includes a body part 222 and a cover part 225. The body part 222 covers the semiconductor, the substrate 210, and a portion of the power terminal 230. The cover part 225 is provided to extend to the outside of the body part 222 by a predetermined length so that a lower area of the molding part 220 is larger than an upper area of the heat dissipation member 240. In one example, the cover part 225 may be provided at a lower end of the body. In addition, the cover part 225 may be provided in a direction parallel to the extension 231. As the cover part 225 is provided, the insulating distance A between the substrate 210 and the power terminal 230 increases.

In one example, the heat dissipation member 240 may include a contact part 242 in contact with the substrate 210 and a step part 244 having a larger area than the contact part 242 and forming a step from the contact part 242 under the contact part 242. In one example, the cover part 225 may be provided on the step part 244. Since the cover part 225 is provided so that the lower area of the molding part 220 is larger than the upper area of the heat dissipation member 240, a separate insulating layer may not be formed between the molding part 220 and the heat dissipation member 240. In addition, as the cover part 225 is provided on the step part 244, it is possible to secure structural stability of the power semiconductor module.

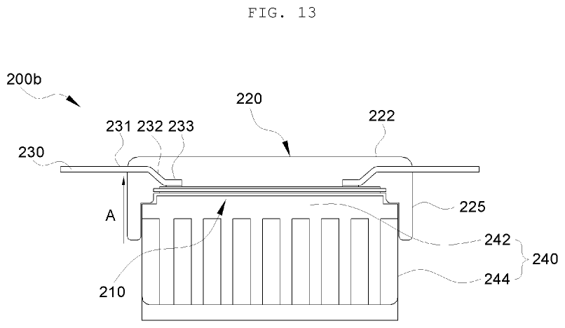

FIG. 13 is a diagram illustrating a power semiconductor module 200b according to another embodiment of the present invention.

Referring to FIG. 13, the cover part 225 may extend downward along an edge of the heat dissipation member 240 to cover the upper portion of the heat dissipation member 240. The cover part 225 may be provided in a direction perpendicular to the extension 231. As the cover part 225 is provided in the direction perpendicular to the extension 231, the effect that the overall volume of the power semiconductor module is not excessively large, but the insulating distance A between the substrate 210 and the power terminal 230 may be lengthened may be provided. In addition, as the cover part 225 is provided to cover the heat dissipation member 240, there is an advantage in securing the structural stability of the power semiconductor module 200.

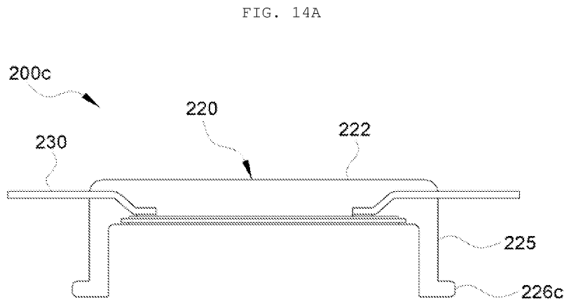

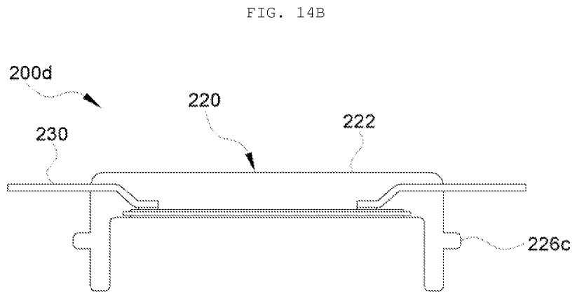

FIGS. 14A to 14C are diagrams illustrating power semiconductor modules 200c, 200d, and 2000e according to another embodiment of the present invention. Referring to FIGS. 14A to 14C, in addition to the embodiment of FIG. 13, a protrusion 226 may be formed in an outside direction of the cover part 225. The protrusion 226 may provide the effect of increasing the insulating distance A between the substrate 210 and the power terminal 230 compared to the embodiment of FIG. 13. Referring to FIG. 14A, the protrusion 226 may be provided at a lower end of the cover part 225. Alternatively, referring to FIG. 14B, the protrusion may be provided to protrude outward from any one point among edges of the cover part 225 in a longitudinal direction. Alternatively, referring to FIG. 14C, the plurality of protrusions 226 may be provided.

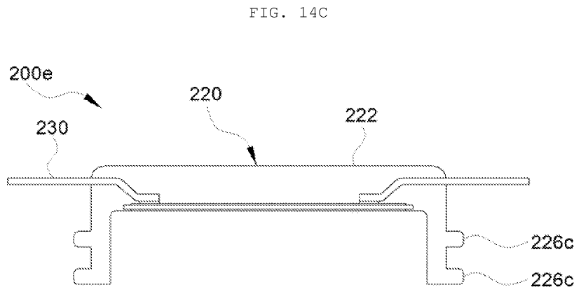

FIG. 15 is a diagram illustrating a power semiconductor module 200f according to another embodiment of the present invention.

Referring to FIG. 15, in one example, the cover part 225 may include an inclined part 227 provided to have a predetermined downward inclination from the body part 222, and an extending cover part 228 extending downward along the edge of the heat dissipation member 240 by being bent from the inclined part 227 to cover the upper portion of the heat dissipation member 240. In one example, the extending cover part 228 may be provided in a direction perpendicular to the extension 231. In one example, the inclined part 227 may be provided on the step part 244 of the heat dissipation member 240, and the extending cover part 228 may be provided to cover an upper edge of the step part 244. Accordingly, there is an advantage in securing the structural stability of the power semiconductor module 200.

The extending cover part 228 may be provided in a direction perpendicular to the extension 231. As the cover part 225 is provided in the direction perpendicular to the extension 231, the effect that the overall volume of the power semiconductor module is not excessively large, but the insulating distance A between the substrate 210 and the power terminal 230 may be lengthened may be provided. In addition, as the extending cover part 228 is provided to cover the heat dissipation member 240, there is an advantage in securing the structural stability of the power semiconductor module 200.

The inclined part 227 is provided so that the power terminal 230 and the molding part 220 may be spaced apart from each other with a predetermined angle. Accordingly, it is possible to prevent the length of the power terminal 230 from becoming excessively long and secure the insulating distance A between the power terminal 230 and the substrate 210. In one example, the inclined part 227 may be provided so that an inner side adjacent to the step part 244 is spaced apart from the contact part 242 with a predetermined gap. For example, a groove may be formed on the inner side adjacent to the step part 244 of the inclined part 227. Accordingly, there is an advantage in that the material cost of the molding part 220 may be reduced by minimizing the volume of the molding part 220.

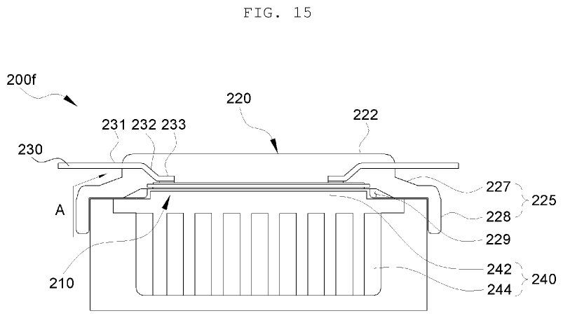

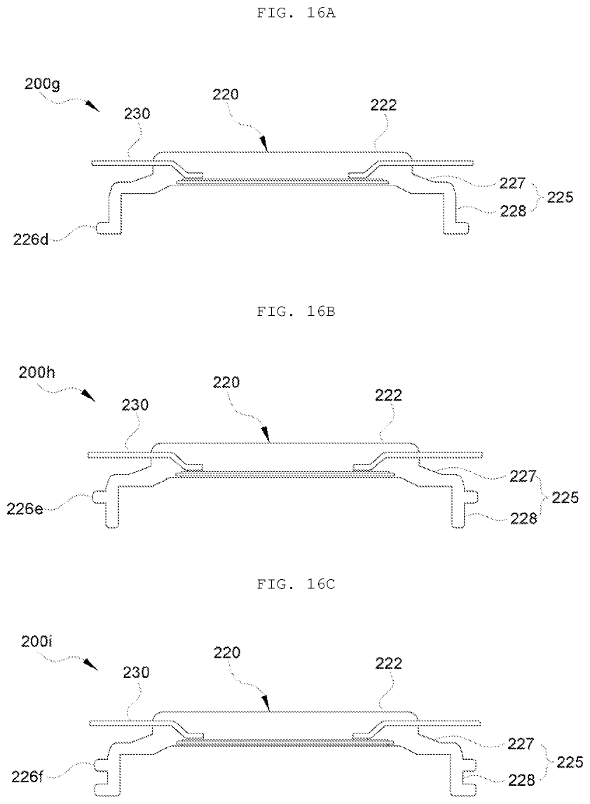

FIGS. 16A to 16C are diagrams illustrating power semiconductor modules 200g, 200h, and 200i according to another embodiment of the present invention. Referring to FIGS. 16A to 16C, in addition to the embodiment of FIG. 5, the protrusion 226 may be formed in an outside direction of the extending cover part 228. The protrusion 226 may provide the effect of increasing the insulating distance A between the substrate 210 and the power terminal 230 compared to the embodiment of FIG. 5. Referring to FIG. 16A, the protrusion 226 may be provided at the lower end of the cover part 225. Alternatively, referring to FIG. 16B, the protrusion may be provided to protrude outward from any one point among the edges of the cover part 225 in the longitudinal direction. Alternatively, referring to FIG. 16C, the plurality of protrusions 226 may be provided.

According to the present invention, there is an advantage that the length of the power terminal 230 does not need to be excessively long.

According to the present invention, there is an advantage of reducing stray inductance through the shape of the molding part 220 and securing the insulating distance between the substrate 210 and the power terminal 230.

In addition, according to the present invention, since a separate insulating layer needs not be provided between the heat dissipation member 240 and the molding part 220, there is an advantage in providing a power semiconductor module 200 that requires low manufacturing costs.

According to the means for solving the problem of the present invention described above, in the power semiconductor module and method of manufacturing the same according to the present invention, since the power terminal is installed to extend in the direction perpendicular to one surface of the substrate, the volume of the molding part may be reduced to secure the insulating distance, so it is possible to allow the power semiconductor module to have the smaller volume.

In addition, since the length of the power terminal may be shorter, it is possible to reduce the inductance of the power semiconductor module.

In addition, since there is no need to install the power terminal on the substrate so that the power terminal protrudes in the side direction parallel to the substrate, the power terminal may be freely arranged at a position on the power semiconductor module, so it is possible to increase the degree of freedom of installation of the power terminal on the substrate.

In addition, the power semiconductor module may be sized and configured to have a smaller volume than a conventional power semiconductor module.

In addition, the power semiconductor module may be sized and configured to have a reduced inductance as compared with a conventional power semiconductor module.

The above description of the present invention is for illustrative purposes, and those skilled in the art to which the present invention pertains will understand that it may be easily modified to other specific forms without changing the technical spirit or essential features of the present invention. Therefore, it should be understood that the above-mentioned embodiments are exemplary in all aspects but are not limited thereto. For example, each component described as a single type may be implemented in a distributed manner, and similarly, components described as distributed may be implemented in a combined form.

It is to be understood that the scope of the present invention will be defined by the claims rather than the above-described description and all modifications and alternations derived from the claims and their equivalents are included in the scope of the present invention.

What is claimed is:

1. A power semiconductor module, comprising:
a substrate including:
an insulating layer including an upper surface and a lower surface;
a first metal layer including a lower surface coupled to the upper surface of the insulating layer; and
a second metal layer including an upper surface coupled to the lower surface of the insulating layer;
a semiconductor coupled to an upper surface of the first metal layer, the semiconductor electrically connected to at least a portion of the first metal layer;
a power terminal including one end coupled to an upper surface of the first metal layer and electrically connected to at least a portion of the first metal layer so that an imaginary line segment connecting one end and the other end is perpendicular to the upper surface of the first metal layer; and
a molding part coupled to the substrate to surround the second metal layer excluding a lower surface of the second metal layer, the power terminal excluding the other end of the power terminal, the insulating layer, the first metal layer, and the semiconductor.

2. The power semiconductor module of claim 1, wherein the power terminal is formed to extend in a longitudinal direction.

3. The power semiconductor module of claim 1, wherein the power terminal comprises at least one of copper, a copper alloy, aluminum, an aluminum alloy, a light metal material, a heat-treated material, a porous material, or any combination thereof.

4. The power semiconductor module of claim 2, wherein the insulating layer comprises ceramic, and the first metal layer and the second metal layer each comprises at least one of copper, aluminum, or a combination thereof.

5. A method of manufacturing a power semiconductor module, the method comprising:
a preparation step of preparing a substrate including an insulating layer including an upper surface and a lower surface, a first metal layer including a lower surface coupled to the upper surface of the insulating layer, and a second metal layer including an upper surface coupled to the lower surface of the insulating layer;
a first installation step of coupling a semiconductor to an upper surface of the first metal layer to be electrically connected to at least a portion of the first metal layer;
a second installation step of coupling a power terminal, the power terminal including a first end coupled to the upper surface of the first metal layer and is electrically connected to at least a portion of the first metal layer so that an imaginary line segment connecting one end, and a second end directed toward an upper portion of the upper surface of the first metal layer;
a molding step of arranging the substrate in an internal space surrounded by a lower molding mold and an upper molding mold and injecting a molding material into the internal space to form a molding part coupled to the substrate; and
a separation step of separating the substrate from the lower molding mold and the upper molding mold,
wherein, when the substrate is arranged in the internal space and the upper molding mold presses the second end of the power terminal, the second end of the power terminal is bent in a direction toward the first end.

6. The method of claim 5, wherein the power terminal comprises an elastomer.

7. The method of claim 5, wherein, when the substrate is arranged in the internal space and the upper molding mold presses the second end of the power terminal, a shape of the power terminal is deformed so that a distance between the first end and the second end is shortened.

8. The method of claim 5, further comprising:
after the separation step, a removal step of removing at least a portion of the protective member coupled to the substrate so that the second end of the power terminal is externally exposed.

9. The method of claim 8, wherein, when the substrate is arranged in the internal space, the distance between the first end and the second end of the power terminal is
longer than the distance between the first end of the power terminal and the protective member, and
shorter than the distance between the first end of the power terminal and a surface of the upper molding mold.

10. The method of claim 5, further comprising:
after the separation step, a processing step of removing at least a portion of the molding part coupled to the substrate so that the second end of the power terminal is exposed externally,
wherein, when the substrate is arranged in the internal space, the distance between the first end and the second end of the power terminal is shorter than the distance between the first end of the power terminal and a surface of the upper molding mold opposite to the lower molding mold.

11. A power semiconductor module comprising:
a substrate on which a conductive pattern is formed;
a power terminal coupled to the substrate and electrically connected to at least some of the patterns;
a semiconductor installed on the substrate and electrically connected to at least some of the patterns and the power terminal;
a molding part covering the semiconductor and the substrate; and
a heat dissipation member provided under the substrate to cool the substrate,
wherein the molding part includes:
a body part covering the semiconductor, the substrate, and a portion of the power terminal; and
a cover part provided to extend to an outside of the body part by a predetermined length so that a lower area of the molding part is larger than an upper area of the heat dissipation member.

12. The power semiconductor module of claim 11,
wherein the power terminal includes:
a coupling part coupled to the substrate;
a bent part bent at a predetermined angle from the coupling part; and
an extension extending from the bent part to the outside of the molding part in a direction parallel to the substrate, and
wherein the cover part is provided in a direction parallel to the extension.

13. The power semiconductor module of claim 11, wherein the cover part is provided at a lower end of the body.

14. The power semiconductor module of claim 11,
wherein the heat dissipation member includes:
a contact part in contact with the substrate; and
a step part having a larger area than the contact part and forming a step with respect to the contact part under the contact part, and
wherein the cover part is provided on the step part.

15. The power semiconductor module of claim 11, wherein the cover part extends downward along an edge of the heat dissipation member to cover an upper portion of the heat dissipation member.

16. The power semiconductor module of claim 15, wherein a protrusion is formed toward the outside of the cover part.

17. The power semiconductor module of claim 14,
wherein the power terminal includes:
a coupling part coupled to the substrate;
a bent part bent at a predetermined angle from the coupling part; and
an extension extending from the bent part to an outside of the molding part in a direction parallel to the substrate, and
wherein the cover part is provided in a direction perpendicular to the extending part.

18. The power semiconductor module of claim 17,
wherein the cover part includes:
an inclined part provided to have a predetermined downward inclination from the body part; and
an extending cover part bent from the inclined part and extending downward along an edge of the heat dissipation member to cover an upper part of the heat dissipation member, and
wherein the cover part is provided in a direction perpendicular to the extending part.

19. The power semiconductor module of claim 18,
wherein the heat dissipation member includes:
a contact part in contact with the substrate; and
a step part having a larger area than the contact part and forming a step with respect to the contact part under the contact part, and
wherein the inclined part is provided on the step part and the extending cover part is provided to cover an upper edge of the step part.

20. The power semiconductor module of claim 19, wherein the inclined part is provided so that an inner side adjacent to the step part is spaced apart from the contact part with a predetermined gap.
